(19) United States
(12) Patent Application Publication
(10) Pub. No.: US 2009/0021921 A1
(43) Pub. Date: Jan. 22, 2009

(54) Memory card and its manufacturing method

(75) Inventors: Sang Jae Jang, Kwangjin-gu (KR); Chul Woo Park, Kangdong-gu (KR); Suk Ku Ko, Kangdong-gu (KR); Choon Heung Lee, Kwangju-si (KR)

Correspondence Address: STETINA BRUNDA GARRED & BRUCKER, 75 ENTERPRISE, SUITE 250, ALISO VIEJO, CA, 92656, US

(73) Assignee: Amkor Technology, Inc.

(21) Appl. No.: 11/114,342

(22) Filed: Apr. 26, 2005

(51) Int. Cl. H05K 1/14

(52) U.S. Cl. 361/737; 361/752

(57) ABSTRACT

A memory card comprising a circuit board having opposed upper and lower circuit board surfaces, multiple side edges, a chamfer extending between a pair of the side edges, a plurality of pads disposed on the lower circuit board surface, and a conductive pattern which is disposed on the upper circuit board surface and electrically connected to the pads. At least one electronic circuit device is attached to the upper circuit board surface and electrically connected to the conductive pattern of the circuit board. A body at least partially encapsulates the circuit board and the electronic circuit element such that a section of the upper circuit board surface extending along the entirety of the chamfer is not covered by the body.

### CROSS-REFERENCE TO RELATED APPLICATIONS

Not Applicable

### STATEMENT RE: FEDERALLY SPONSORED RESEARCH/DEVELOPMENT

Not Applicable

### BACKGROUND OF THE INVENTION

The present invention relates generally to memory cards, and more particularly to a memory card (e.g., a multi-media card (MMC), a secure digital card (SD), etc.) which is configured to include at least one I/O pad adjacent the chamfer of a substrate (e.g., a printed circuit board (PCB)) which is itself integrated into a module of the card. Further in accordance with the present invention, there is provided various methods which may be employed to facilitate the efficient, cost effective simultaneous fabrication of a plurality of modules which each include a substrate having an I/O pad adjacent the chamfer thereof.

As is well known in the electronics industry, memory cards are being used in increasing numbers to provide memory storage and other electronic functions for devices such as digital cameras, MP3 players, cellular phones, and personal digital assistants. In this regard, memory cards are provided in various formats, including multi-media cards and secure digital cards.

Typically, memory cards comprise multiple integrated circuit devices or semiconductor dies which are interconnected using a circuit board substrate. Memory cards also include electrical contacts for providing an external interface to an insertion point or socket. These electrical contacts are typically exposed on the backside of the circuit board substrate, with the electrical connection to the dies being provided by vias which extend through the circuit board substrate. The prior art memory cards typically have a generally rectangular configuration, with a chamfer being included at one of the corner regions thereof. The contacts of the memory card usually extend along one of the lateral sides or edges of the card to but not along the chamfer thereof. In this regard, currently known manufacturing methodologies for the mass production of memory cards are not well suited for the cost effective, simultaneous manufacture of a plurality of circuit board substrates which each include at least one extra I/O pad positioned along and adjacent to the card chamfer. The inclusion of one or more additional I/O pads along the card chamfer is highly desirable due to the resultant improvement in the data transfer capacity of the card which is an emerging requirement in many applications.

The present invention addresses and overcomes the above-described shortcomings of the prior art by providing various methods which may be employed to facilitate the efficient, cost effective simultaneous fabrication of a plurality of modules which each include a substrate (e.g., a printed circuit board (PCB)) having at least one I/O pad adjacent a chamfer formed therein. These modules are each integrated into a memory card which is configured to include at least one additional I/O pad adjacent the chamfer defined thereby. These and other attributes of the present invention will be described in more detail below.

### BRIEF SUMMARY OF THE INVENTION

In accordance with the present invention, there is provided various methods which may be employed to facilitate the efficient, cost effective simultaneous fabrication of a plurality of modules which each include a substrate (e.g., a printed circuit board (PCB)) having a plurality of I/O pads, including at least one I/O pad which is disposed adjacent a chamfer formed in the substrate. The I/O pads are electrically connected to one or more electronic circuit elements which are mounted to the substrate. The substrate and electronic circuit element(s) mounted thereto are partially encapsulated with a body, the combination of the substrate, electronic circuit elements and body collectively defining the module. The module is partially covered by a lid or cover to complete the fabrication of the memory card which is configured to include at least one additional I/O pad adjacent the chamfer defined thereby.

The present invention is best understood by reference to the following detailed description when read in conjunction with the accompanying drawings.

### BRIEF DESCRIPTION OF THE DRAWINGS

These, as well as other features of the present invention, will become more apparent upon reference to the drawings wherein:

FIG. 1A is a top perspective view of a memory card constructed in accordance with one embodiment of the present invention;

FIG. 1B is a bottom perspective view of the memory card shown in FIG. 1A;

FIG. 1C is a cross-sectional view of the memory card taken along line 1-1 of FIG. 1B;

FIG. 1D is a top plan view of the module of the memory card shown in FIGS. 1A and 1B;

FIG. 1E is a top plan view of a substrate assembly which is configured to facilitate the simultaneous fabrication a plurality of modules which each have the configuration shown in FIG. 1D;

FIG. 2A is a top plan view of the module of the memory card constructed in accordance with another embodiment of the present invention;

FIG. 2B is a top plan view of a substrate assembly which is configured to facilitate the simultaneous fabrication a plurality of modules which each have the configuration shown in FIG. 2A;

FIG. 2C is a cross-sectional view of a memory card formed to include the module shown in FIG. 2A;

FIG. 3 is a top plan view of a substrate assembly which is configured to facilitate the simultaneous fabrication a plurality of modules which are each constructed in accordance with another embodiment of the present invention;

FIG. 4A is a top plan view of the module of the memory card constructed in accordance with another embodiment of the present invention;

FIG. 4B is a top plan view of a substrate assembly which is configured to facilitate the simultaneous fabrication a plurality of modules which each have the configuration shown in FIG. 4A; and

FIG. 5 is a cross-sectional view of a memory card constructed in accordance with another embodiment of the present invention.

Common reference numerals are used throughout the drawings and detailed description to indicate like elements.

### DETAILED DESCRIPTION OF THE INVENTION

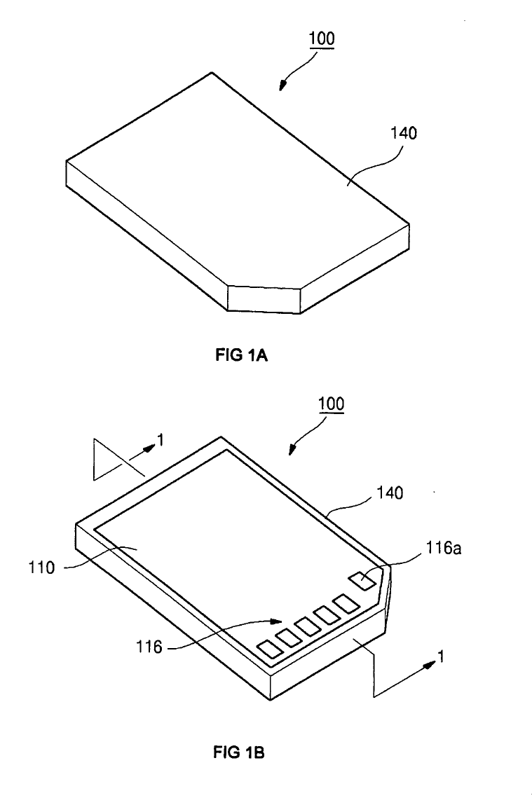

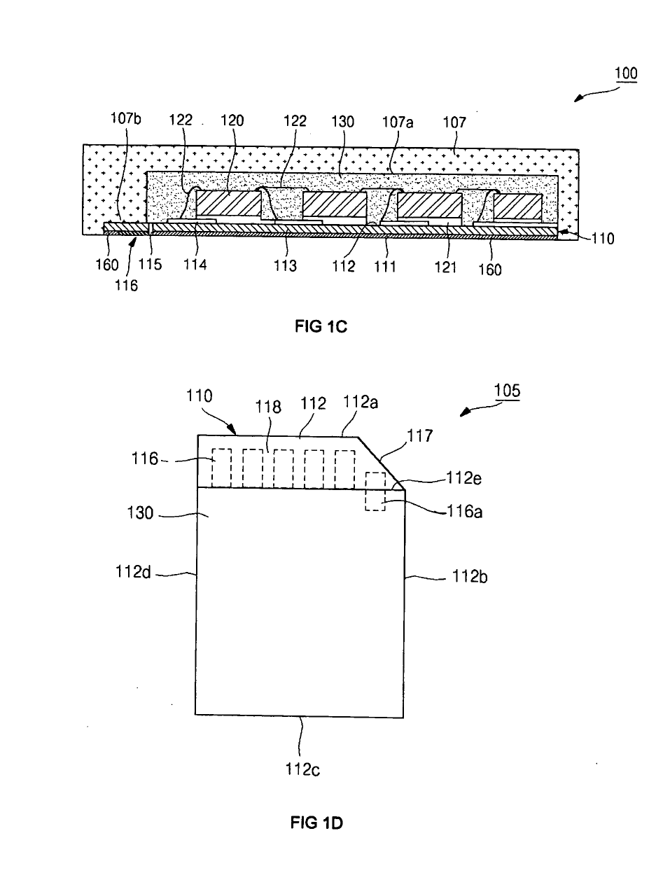

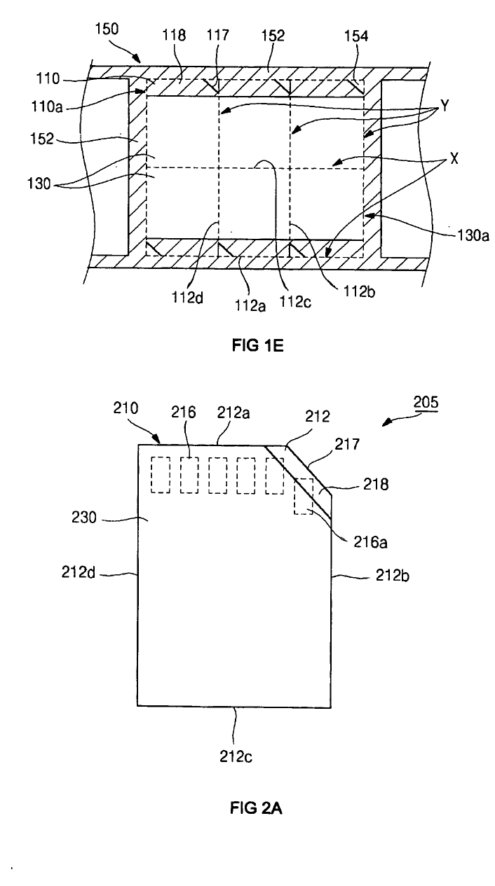

Referring now to the drawings wherein the showings are for purposes of illustrating preferred embodiments of the present invention only, and not for purposes of limiting the same, FIGS. 1A-1C depict a memory card 100 constructed in accordance with one embodiment of the present invention. As is best seen in FIGS. 1B-1D, the memory card 100 includes a substrate, and more particularly a circuit board 110 which has a generally quadrangular configuration. The circuit board 110 includes an insulative layer 113 which has a generally planar lower surface 111, and an opposed, generally planar upper surface 112. Formed on the upper surface 112 of the insulative layer 113 is an electrically conductive pattern 114. Formed on the lower surface 111 of the insulative layer 113 is a plurality of contacts or I/O pads 116, 116a. In the circuit board 110, the conductive pattern 114 is electrically connected to the I/O pads 116, 116a by one or more conductive vias 115 which extend through the insulative layer 113. The circuit board 110, and in particular the insulative layer 113 thereof, may be a hardened printed circuit board, a flexible printed circuit board, or its equivalent, the present invention not being limited to any particular material for the insulative layer 113.

As is seen in FIG. 1D, the insulative layer 113 of the circuit board 110 defines an opposed pair of lateral peripheral edge segments or edges 112a, 112c, and an opposed pair of longitudinal peripheral edge segments or edges 112b, 112d. Extending angularly between the lateral edge 112a and the longitudinal edge 112b is a chamfer 117 which is also defined by the insulative layer 113. The I/O pads 116 are arranged in a row and are disposed in spaced relation to the lateral edge 112a and to each other. The at least one I/O pad 116a included in the circuit board 110 is set back relative to the remaining I/O pads 116 and is disposed along and adjacent to the chamfer 117. As indicated above, the I/O pad 116a, along with the I/O pads 116, is electrically connected to the conductive pattern 114 by the via(s) 115.

As further seen in FIG. 1C, in the memory card 100, one or more electronic circuit devices 120 are bonded to the upper surface 112 of the circuit board 110 through the use of an adhesive 121. The electronic circuit devices 120 may comprise semiconductor packages, semiconductor dies, and passive elements. However, passive elements may not be included with the electronic circuit devices 120. The electronic circuit device(s) 120 is/are electrically connected to the conductive pattern 114 through the use of one or more conductive wires 122. Though, in FIG. 1C, four electronic circuit devices 120 are depicted as being attached to the circuit board 110 and electrically connected to the conductive pattern 114 and to each other through the use of conductive wires 122, those of ordinary skill in the art will recognize that this particular combination is illustrative only, and that nature and number of the electronic circuit devices 120 integrated into the memory card 110 and the pattern of electrical communication between such electronic circuit device(s) 120 and the conductive pattern 114 and/or each other maybe varied according to a prescribed application for the memory card 100. Still further, it is contemplated that the present invention may employ other bonding methods, such as a flip chip bonding method, as an alternative or in addition to the illustrated wire bonding method employing the use of the conductive wires 122.

As seen in FIGS. 1C and 1D, the circuit board 110, electronic device(s) 120 and the conductive wire(s) 122 are at least partially encapsulated by an encapsulant body 130 to protect the same from the external environment. Though the body 130 covers the electronic circuit device(s) 120, the conductive wire(s) 122, the conductive pattern 114 and a substantial portion of the upper surface 112 of the insulative layer 113, the body 130 does not cover the entirety of the upper surface 112. Rather, the body 130 is formed such that it terminates at a phantom line 112e which extends generally perpendicularly between the longitudinal edges 112b, 112d at a point at or slightly below the contact point or junction between the chamfer 117 and longitudinal edge 112b. Thus, the phantom line 112e extends in spaced, generally parallel relation to the lateral edges 112a, 112c of the insulative layer 113. If spaced slightly below the junction between the chamfer 117 and longitudinal edge 112b, the phantom line 112e will be oriented slightly closer to the lateral edge 112c then as shown in FIG. 1D. Thus, the body 130, while extending to and in generally flush relation with the lateral edge 112c and longitudinal edges 112b, 112d, does not extend beyond the phantom line 112e shown in FIG. 1D. As a result, the body 130 is spaced from the chamfer 117, such spacing occurring for reasons which will be described in more detail below.

The fully formed body 130 defines a generally planar upper surface, as well as generally planar side surfaces which, as indicated above, are substantially flush with respective ones of the lateral edge 112c and longitudinal edges 112b, 112d of the insulative layer 113. Since the body 130 does not extend beyond the phantom line 112b as described above, a section 118 of the circuit board 110, and in particular the upper surface 112 of the insulative layer 113 thereof, is exposed since it is not covered by the body 130. In the memory card 100, the combination of the circuit board 110, electronic circuit device(s) 120, conductive wire(s) 122 and body 130 collectively define a module 105 of the memory card 100. The encapsulant material used to form the body 130 may include, for example, an epoxy, a plastic molding compound, or equivalents thereto, the present invention not being limited to any specific material for the body 130.

As best seen in FIGS. 1A, 1B and 1C, the memory card 100 further comprises a case or cover 107 which is secured to the module 105. The cover 107 includes a recess 107a which is formed to have a shape corresponding or complimentary to those surfaces of the module 105 which are ultimately covered by the cover 107 as is seen in FIG. 1C. As such, the recess 107a includes a stepped portion 107b which is configured to make contact with the exposed section 118 of the module 105. As will be recognized, other portions of the recess 107a have contours which correspond to the exposed surfaces of the body 130 and to the lateral and longitudinal edges 112a, 112c, 112b, 112d of the insulative layer 113 of the circuit board 110. Those of ordinary skill in the art will recognize that the shape or configuration of the recess 107a may vary depending on the particular shape of the upper portion of the module 105. It is contemplated that the upper surface of the body 130 of the module 105 will be bonded to the corresponding surface of the recess 107a through the use of a suitable adhesive.

As further seen in FIG. 1C, subsequent to the attachment of the cover 107 to the module 105, a label 160 may optionally be bonded or adhered to the lower surface 111 of the insulative layer 113 of the circuit board 110. It is contemplated that any such label 160 will be formed with one or more holes or openings for facilitating the exposure of the I/O pads 116, 116a. If the label 160 is included in the memory card 100, the lower surface 111 of the insulative layer 113 is not exposed, thus improving the external appearance of the memory card 100. The label 160, if included in the memory card 100, may be used to identify the manufacturer of the memory card 100 and other information pertinent thereto. As indicated above, the label 160 is an option for inclusion in the memory card 100, and typically will not be used if the memory card 100 is intended for installation within an appliance.

Referring now to FIG. 1E, there is shown a raw substrate assembly 150 which will be used to describe one methodology for facilitating the cost effective, simultaneous manufacture of a plurality of modules 105, each of which is adapted for integration into a memory card 100. The substrate assembly 150 includes a substrate 152 which is formed of a suitable printed circuit board material, and in particular that material which will ultimately form the insulative layer 113 of each of the resultant modules 105. It is contemplated that the substrate 152 will be sized so as to be capable of defining at least one circuit board matrix 110a which will ultimately facilitate the creation of six modules 105. In FIG. 1E, one circuit board matrix 110a is shown with particularity. It is contemplated that the substrate 152 will typically be sized to have the capability of allowing three or more circuit board matrices 110a to be defined thereon.

As indicated above, it is contemplated that each circuit board matrix 110a included on the substrate 152 will be configured to ultimately facilitate the formation of six modules 105. Thus, within each circuit board matrix 110a are six separate circuit boards 110 which each have the aforementioned structural attributes, and are ultimately separated from each other as a result of the saw singulation of the substrate 152 in a prescribed manner. In one of the initial stages of the fabrication process for the module 105, the substrate 152 is patterned in a manner facilitating the formation of six separate conductive patterns 114 and six separate sets of I/O pads 116, 116a upon respective ones of the six insulative layers 113 within each circuit board matrix 110a. Either prior or subsequent to the formation of the conductive patterns 114 and I/O pads 116, 116a within each circuit board matrix 110a, a punching, routing or laser operation is completed upon the substrate 152 in a manner facilitating the formation of six separate triangularly configured openings 154 within each circuit board matrix 110a, each opening 154 being located in a respective one of the insulative layers 113. As will be recognized, the relative positioning of the openings 154 and I/O pads 116, 116a within the circuit boards 110 of the circuit board matrix 110a is such that the spacial relationship between each of the six I/O pads 116a and a respective one of the openings 154 within each circuit board 110 is the same as that shown and described above in relation to FIG. 1D, considering that each opening 154 ultimately defines a respective chamfer 117 subsequent to the completion of the singulation process.

To facilitate the formation of the six modules 105 from each circuit board matrix 110a, it is contemplated that the substrate 152 will ultimately be cut or severed along each of four Y axes and each of three X axes. When viewed from the perspective shown in FIG. 1E, each of the four Y axes is generally vertical, with each of the three X axes being generally horizontal and extending substantially perpendicularly relative to the Y axes. Due to the orientations of the X and Y axes relative to each other, the layout of each circuit board matrix 110a lends itself to the ultimate fabrication of six modules 105. The layout of such modules 105 prior to the singulation of the substrate assembly 150 is in two horizontal rows of three (defined by the X axes) and three vertical columns of two (defined by the Y axes). It is contemplated that the patterning of the substrate 152 to define the conductive patterns 114 and I/O pads 116, 116a will be facilitated such that each of the openings 154 included in the upper row will be oriented approximately 180 degrees relative to the opening 154 in the corresponding column of the lower row. As indicated above, the number of openings 154 included in each circuit board matrix 110a corresponds to the number of modules 105 which will ultimately be defined thereby when the substrate 152 is saw singulated along the X and Y axes.

Subsequent to the formation of the conductive patterns 114, I/O pads 116, 116a and openings 154 within each circuit board matrix 110a of the substrate 152, the electronic circuit devices 120 are attached to each of the circuit boards 110 within the circuit board matrix 110a, and electrically connected to a corresponding one of the conductive patterns 114 through the use of the conductive wires 122. Thereafter, a mold cap 130a is formed on the substrate 152 in a manner covering a portion of the circuit board matrix 110a. As is seen in FIG. 1E, the mold cap 130a is formed such that the electronic circuit devices 120, conductive wires 122 and portions of each of the circuit boards 110 within the corresponding circuit board matrix 110a are covered in the same manner described above in relation to FIG. 1D. In this regard, the mold, which has a structure corresponding to the ultimate shape of the mold cap 130a, makes direct contact with the section 118 of each circuit board 110 within the circuit board matrix 110a, thus effectively covering and sealing each of the openings 154. As a result, since the mold shields the openings 154, the encapsulant used to form the mold cap 130a does not flow to the lower surface 111 of any one of the circuit boards 110 included in the circuit board matrix 110a during the process of forming the mold cap 130a, thus insuring that no contamination of any lower surface 111 of any circuit board 110 occurs. Due to the contact between the mold and the section 118 of each circuit board 110 within the circuit board matrix 110a, such sections 118 remain uncovered by the mold cap 130a upon the completion of the formation thereof.

Subsequent to the formation of the mold cap 130a, the substrate 152 is subjected to a saw singulation process along the X and Y axes of each circuit board matrix 110a. Such singulation effectively separates each circuit board matrix 110a into six separate modules 105. As will be recognized, the singulation along the central one of the three X axes defines the lateral edges 112c of the resultant six modules 105, with the singulation along the uppermost and lowermost X axes facilitating the formation of the lateral edges 112a. The singulation along the four Y axes facilitates the formation of the longitudinal edges 112b, 112d of the resultant six modules 105. As indicated above, the formation of the openings 154 within each circuit board matrix 110a ultimately facilitates the formation of each chamfer 117 within a respective one of the six resultant modules 105. The singulation of the mold cap 130a along the X and Y axes facilitates the formation of the bodies 130 of the resultant modules 105. After each module 105 has been fully formed as a result of the completion of the above-described singulation process, the aforementioned cover 107 may be attached to each such module 105, thus completing the fabrication of the memory card 100.

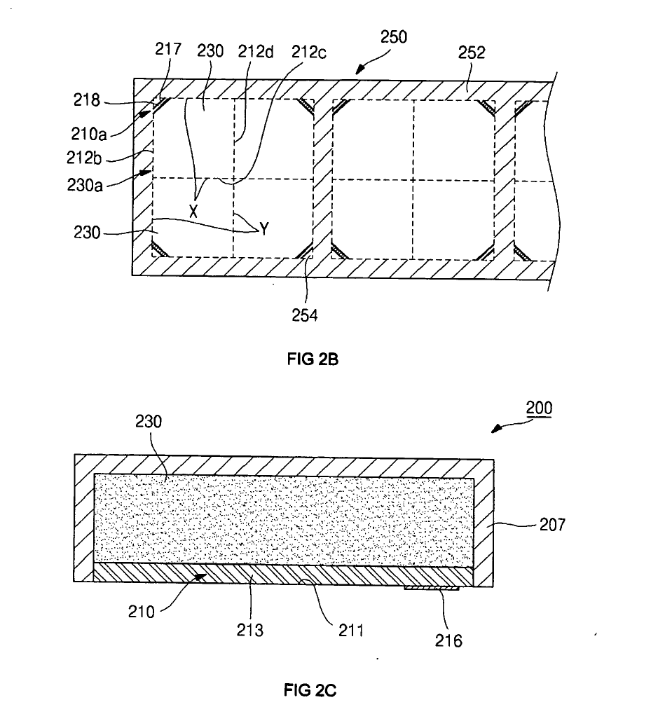

Referring now to FIGS. 2A-2C, there is shown a memory card 200 constructed in accordance with another embodiment of the present invention. As is best seen in FIGS. 2A and 2C, the memory card 200 includes a substrate, and more particularly a circuit board 210 which has a generally quadrangular configuration. The circuit board 210 includes an insulative layer 213 which has a generally planar lower surface 211, and an opposed, generally planar upper surface 212. Formed on the upper surface 212 of the insulative layer 213 is an electrically conductive pattern. Formed on the lower surface 211 of the insulative layer 213 is a plurality of contacts or I/O pads 216, 216a. In the circuit board 210, the conductive pattern is electrically connected to the I/O pads 216, 216a by one or more conductive vias which extend through the insulative layer 213. The circuit board 210, and in particular the insulative layer 213 thereof, may be a hardened printed circuit board, a flexible printed circuit board, or its equivalent, the present invention not being limited to any particular material for the insulative layer 213.

As is seen in FIG. 2A, the insulative layer 213 of the circuit board 210 defines an opposed pair of lateral peripheral edge segments or edges 212a, 212c, and an opposed pair of longitudinal peripheral edge segments or edges 212b, 212d. Extending angularly between the lateral edge 212a and the longitudinal edge 212b is a chamfer 217 which is also defined by the insulative layer 213. The I/O pads 216 are arranged in a row and are disposed in spaced relation to the lateral edge 212a and to each other. The at least one I/O pad 216a included in the circuit board 210 is set back relative to the remaining I/O pads 216 and is disposed along and adjacent to the chamfer 217.

Though not shown, in the memory card 200, one or more electronic circuit devices are bonded to the upper surface 212 of the circuit board 210 and electrically connected to the conductive pattern through the use of one or more conductive wires in the same manner described above in relation to the memory card 100. The circuit board 210, electronic device(s) mounted thereto and the conductive wire(s) used to electrically connect the electronic cicuit device(s) to the I/O pads 216, 216a are at least partially encapsulated by an encapsulant body 230 to protect the same from the external environment. Though the body 230 covers a substantial portion of the upper surface 212 of the insulative layer 213, the body 230 does not cover the entirety of the upper surface 212. Rather, the body 230 is formed such that it terminates inwardly from the chamfer 217 in the manner shown in FIG. 2A. Thus, the body 230 defines a generally planar side surface which extends in spaced, generally parallel relation to the chamfer 217 from the lateral edge 212a to the longitudinal edge 212b. As such, the body 230, while extending to and in generally flush relation with the lateral edges 212a, 212c and longitudinal edges 212b, 212d, does not extend to the chamfer 217. As a result, the body 230 is spaced from the chamfer 217, such spacing occurring for reasons which will be described in more detail below.

The fully formed body 230 defines a generally planar upper surface, as well as generally planar side surfaces which, as indicated above, are substantially flush with respective ones of the lateral edges 212a, 212c and longitudinal edges 212b, 212d of the insulative layer 213. Since the body 230 does not extend to the chamfer 217 as described above, a section 218 of the circuit board 210, and in particular the upper surface 212 of the insulative layer 213 thereof, is exposed since it is not covered by the body 230. In the memory card 200, the combination of the circuit board 210, electronic circuit device(s), conductive wire(s) and body 230 collectively define a module 205 of the memory card 200. The encapsulant material used to form the body 230 may include, for example, an epoxy, a plastic molding compound, or equivalents thereto, the present invention not being limited to any specific material for the body 230.

As best seen in FIG. 2C, the memory card 200 further comprises a case or cover 207 which is secured to the module 205. The cover 207 includes a recess which is formed to have a shape corresponding or complimentary to those surfaces of the module 205 which are ultimately covered by the cover 207. As such, the recess includes a stepped portion which is configured to make contact with the exposed section 218 of the module 205. As will be recognized, other portions of the recess have contours which correspond to the exposed surfaces of the body 230 and to the lateral and longitudinal edges 212a, 212c, 212b, 212d of the insulative layer 213 of the circuit board 210. Those of ordinary skill in the art will recognize that the shape or configuration of the recess may vary depending on the particular shape of the upper portion of the module 205. It is contemplated that the upper surface of the body 230 of the module 205 will be bonded to the corresponding surface of the recess of the cover 207 through the use of a suitable adhesive.

Referring now to FIG. 2B, there is shown a raw substrate assembly 250 which will be used to describe one methodology for facilitating the cost effective, simultaneous manufacture of a plurality of modules 205, each of which is adapted for integration into a memory card 200. The substrate assembly 250 includes a substrate 252 which is formed of a suitable printed circuit board material, and in particular that material which will ultimately form the insulative layer 213 of each of the resultant modules 205. It is contemplated that the substrate 252 will be sized so as to be capable of defining at least one circuit board matrix 210a which will ultimately facilitate the creation of four modules 205. In FIG. 2B, two circuit board matrices 210a are shown with particularity. It is contemplated that the substrate 252 will typically be sized to have the capability of allowing three or more circuit board matrices 210a to be defined thereon.

As indicated above, it is contemplated that each circuit board matrix 210a included on the substrate 252 will be configured to ultimately facilitate the formation of four modules 205. Thus, within each circuit board matrix 210a are four separate circuit boards 210 which each have the aforementioned structural attributes, and are ultimately separated from each other as a result of the saw singulation of the substrate 252 in a prescribed manner. In one of the initial stages of the fabrication process for the module 205, the substrate 252 is patterned in a manner facilitating the formation of four separate conductive patterns and four separate sets of I/O pads 216, 216a upon respective ones of the four insulative layers 213 within each circuit board matrix 210a. Either prior or subsequent to the formation of the conductive patterns and I/O pads 216, 216a within each circuit board matrix 210a, a punching, routing or laser operation is completed upon the substrate 252 in a manner facilitating the formation of four separate triangularly configured openings 254 within each circuit board matrix 210a, each opening 254 being located in a respective one of the insulative layers 213. As will be recognized, the relative positioning of the openings 254 and I/O pads 216, 216a within the circuit boards 210 of the circuit board matrix 210a is such that the spacial relationship between each of the four I/O pads 216a and a respective one of the openings 254 within each circuit board 210 is the same as that shown and described above in relation to FIG. 2A, considering that each opening 254 ultimately defines a respective chamfer 217 subsequent to the completion of the singulation process.

To facilitate the formation of the four modules 205 from each circuit board matrix 210a, it is contemplated that the substrate 252 will ultimately be cut or severed along each of three Y axes and each of three X axes. When viewed from the perspective shown in FIG. 2B, each of the three Y axes is generally vertical, with each of the three X axes being generally horizontal and extending substantially perpendicularly relative to the Y axes. Due to the orientations of the X and Y axes relative to each other, the layout of each circuit board matrix 210a lends itself to the ultimate fabrication of four modules 205. The layout of such modules 205 prior to the singulation of the substrate assembly 250 is in two horizontal rows of two (defined by the X axes) and two vertical columns of two (defined by the Y axes). It is contemplated that the patterning of the substrate 252 to define the conductive patterns and I/O pads 216, 216a will be facilitated such that the four openings 254 will be located at respective ones of the four corners defined by the circuit board matrix as shown in FIG. 2B. As indicated above, the number of openings 254 included in each circuit board matrix 210a corresponds to the number of modules 205 which will ultimately be defined thereby when the substrate 252 is saw singulated along the X and Y axes.

Subsequent to the formation of the conductive patterns, I/O pads 216, 216a and openings 254 within each circuit board matrix 210a of the substrate 252, the electronic circuit devices are attached to each of the circuit boards 210 within the circuit board matrix 210a, and electrically connected to a corresponding one of the conductive patterns through the use of the conductive wires. Thereafter, a mold cap 230a is formed on the substrate 252 in a manner covering a portion of the circuit board matrix 210a. As is seen in FIG. 2B, the mold cap 230a is formed such that the electronic circuit devices, conductive wires and portions of each of the circuit boards 210 within the corresponding circuit board matrix 210a are covered in the same manner described above in relation to FIG. 2A. In this regard, the mold, which has a structure corresponding to the ultimate shape of the mold cap 230a, makes direct contact with the section 218 of each circuit board 210 within the circuit board matrix 210a, thus effectively covering and sealing each of the openings 254. As a result, since the mold shields the openings 254, the encapsulant used to form the mold cap 230a does not flow to the lower surface 211 of any one of the circuit boards 210 included in the circuit board matrix 210a during the process of forming the mold cap 230a, thus insuring that no contamination of any lower surface 211 of any circuit board 210 occurs. Due to the contact between the mold and the section 218 of each circuit board 210 within the circuit board matrix 210a, such sections 218 remain uncovered by the mold cap 230a upon the completion of the formation thereof.

Subsequent to the formation of the mold cap 230a, the substrate 252 is subjected to a saw singulation process along the X and Y axes of each circuit board matrix 210a. Such singulation effectively separates each circuit board matrix 210a into four separate modules 205. As will be recognized, the singulation along the central one of the three X axes defines the lateral edges 212c of the resultant four modules 205, with the singulation along the uppermost and lowermost X axes facilitating the formation of the lateral edges 212a. The singulation along the three Y axes facilitates the formation of the longitudinal edges 212b, 212d of the resultant four modules 205. As indicated above, the formation of the openings 254 within each circuit board matrix 210a ultimately facilitates the formation of each chamfer 217 within a respective one of the four resultant modules 205. The singulation of the mold cap 230a along the X and Y axes facilitates the formation of the bodies 230 of the resultant modules 205. After each module 205 has been fully formed as a result of the completion of the above-described singulation process, the aforementioned cover 207 may be attached to each such module 205, thus completing the fabrication of the memory card 200.

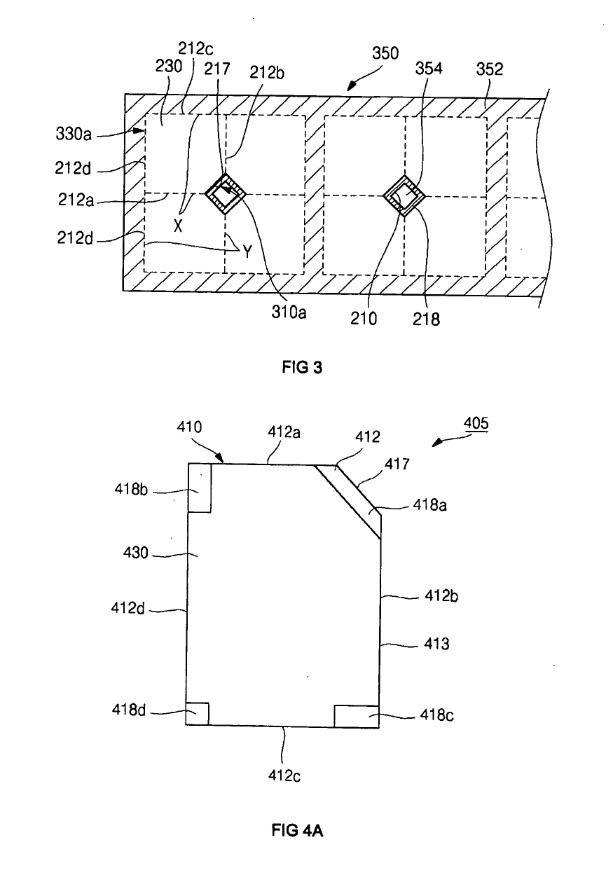

Referring now to FIG. 3, there is shown a raw substrate assembly 350 which will be used to describe another methodology for facilitating the cost effective, simultaneous manufacture of a plurality of modules 205, each of which is adapted for integration into a memory card 200. The substrate assembly 350 includes a substrate 352 which is formed of a suitable printed circuit board material, and in particular that material which will ultimately form the insulative layer 213 of each of the resultant modules 205. It is contemplated that the substrate 352 will be sized so as to be capable of defining at least one circuit board matrix 310a which will ultimately facilitate the creation of four modules 205. In FIG. 3, two circuit board matrices 310a are shown with particularity. It is contemplated that the substrate 352 will typically be sized to have the capability of allowing three or more circuit board matrices 310a to be defined thereon.

As indicated above, it is contemplated that each circuit board matrix 310a included on the substrate 352 will be configured to ultimately facilitate the formation of four modules 205. Thus, within each circuit board matrix 310a are four separate circuit boards 210 which each have the aforementioned structural attributes, and are ultimately separated from each other as a result of the saw singulation of the substrate 352 in a prescribed manner. In one of the initial stages of the fabrication process for the module 205, the substrate 352 is patterned in a manner facilitating the formation of four separate conductive patterns and four separate sets of I/O pads 216, 216a upon respective ones of the four insulative layers 213 within each circuit board matrix 310a. Either prior or subsequent to the formation of the conductive patterns and I/O pads 216, 216a within each circuit board matrix 310a, a punching, routing or laser operation is completed upon the substrate 352 in a manner facilitating the formation of a central, generally quadrangular opening 354 within each circuit board matrix 310a, each opening 354 extending into each of the four insulative layers 213 of the corresponding circuit board matrix 310a. As will be recognized, the relative positioning of the opening 354 and I/O pads 216, 216a within the circuit boards 210 of the circuit board matrix 310a is such that the spacial relationship between each of the four I/O pads 216a and the opening 354 is the same as that shown and described above in relation to FIG. 2A, considering that the opening 354 ultimately defines the chamfers 217 subsequent to the completion of the singulation process.

To facilitate the formation of the four modules 205 from each circuit board matrix 310a, it is contemplated that the substrate 352 will ultimately be cut or severed along each of three Y axes and each of three X axes. When viewed from the perspective shown in FIG. 3, each of the three Y axes is generally vertical, with each of the three X axes being generally horizontal and extending substantially perpendicularly relative to the Y axes. Due to the orientations of the X and Y axes relative to each other, the layout of each circuit board matrix 310a lends itself to the ultimate fabrication of four modules 205. The layout of such modules 205 prior to the singulation of the substrate assembly 350 is in two horizontal rows of two (defined by the X axes) and two vertical columns of two (defined by the Y axes). It is contemplated that the patterning of the substrate 352 to define the conductive patterns and I/O pads 216, 216a will be facilitated such that the opening 354 will be located at the approximate center of the circuit board matrix as shown in FIG. 3.

Subsequent to the formation of the conductive patterns, I/O pads 216, 216a and opening 354 within each circuit board matrix 310a of the substrate 352, the electronic circuit devices are attached to each of the circuit boards 210 within the circuit board matrix 310a, and electrically connected to a corresponding one of the conductive patterns through the use of the conductive wires. Thereafter, a mold cap 330a is formed on the substrate 352 in a manner covering a portion of the circuit board matrix 310a. As is seen in FIG. 3, the mold cap 330a is formed such that the electronic circuit devices, conductive wires and portions of each of the circuit boards 210 within the corresponding circuit board matrix 310a are covered in the same manner described above in relation to FIG. 2A. In this regard, the mold, which has a structure corresponding to the ultimate shape of the mold cap 330a, makes direct contact with the section 218 of each circuit board 210 within the circuit board matrix 310a, thus effectively covering and sealing the opening 354. As a result, since the mold shields the opening 354, the encapsulant used to form the mold cap 330a does not flow to the lower surface 211 of any one of the circuit boards 210 included in the circuit board matrix 310a during the process of forming the mold cap 330a, thus insuring that no contamination of any lower surface 211 of any circuit board 210 occurs. Due to the contact between the mold and the section 218 of each circuit board 210 within the circuit board matrix 310a, such sections 218 remain uncovered by the mold cap 330a upon the completion of the formation thereof.

Subsequent to the formation of the mold cap 330a, the substrate 352 is subjected to a saw singulation process along the X and Y axes of each circuit board matrix 310a. Such singulation effectively separates each circuit board matrix 310a into four separate modules 205. As will be recognized, the singulation along the central one of the three X axes defines the lateral edges 212c of the resultant four modules 205, with the singulation along the uppermost and lowermost X axes facilitating the formation of the lateral edges 212a. The singulation along the three Y axes facilitates the formation of the longitudinal edges 212b, 212d of the resultant four modules 205. As indicated above, the formation of the opening 354 within each circuit board matrix 310a ultimately facilitates the formation of each chamfer 217 within a respective one of the four resultant modules 205. The singulation of the mold cap 330a along the X and Y axes facilitates the formation of the bodies 230 of the resultant modules 205. After each module 205 has been fully formed as a result of the completion of the above-described singulation process, the aforementioned cover 207 may be attached to each such module 205, thus completing the fabrication of the memory card 200.

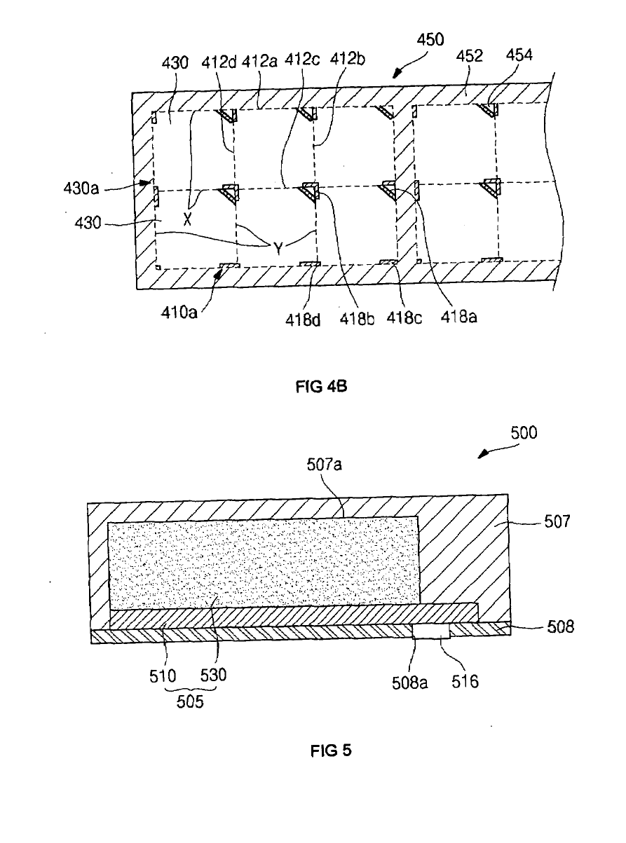

Referring now to FIGS. 4A and 4B, there is shown a module 405 for integration into a memory card constructed in accordance with another embodiment of the present invention. The module 405 bears substantial similarity in construction to the module 205 described above, and may be integrated into the memory card 200 as an alternative to the module 205. As is best seen in FIG. 4A, the module 405 includes a substrate, and more particularly a circuit board 410 which has a generally quadrangular configuration. The circuit board 410 includes an insulative layer 413 which has a generally planar lower surface, and an opposed, generally planar upper surface 412. Formed on the upper surface 412 of the insulative layer 413 is an electrically conductive pattern. Formed on the lower surface of the insulative layer 413 is a plurality of contacts or I/O pads. In the module 405, the conductive pattern is electrically connected to the I/O pads by one or more conductive vias which extend through the insulative layer 413. The circuit board 410, and in particular the insulative layer 413 thereof, may be a hardened printed circuit board, a flexible printed circuit board, or its equivalent, the present invention not being limited to any particular material for the insulative layer 413.

As is seen in FIG. 4A, the insulative layer 413 of the circuit board 410 defines an opposed pair of lateral peripheral edge segments or edges 412a, 412c, and an opposed pair of longitudinal peripheral edge segments or edges 412b, 412d. Extending angularly between the lateral edge 412a and the longitudinal edge 412b is a chamfer 417 which is also defined by the insulative layer 413. The I/O pads are arranged in a row and are disposed in spaced relation to the lateral edge 412a and to each other. At least one I/O pad is set back relative to the remaining I/O pads and is disposed along and adjacent to the chamfer 417.

Though not shown, one or more electronic circuit devices are bonded to the upper surface 412 of the circuit board 410 and electrically connected to the conductive pattern through the use of one or more conductive wires in the same manner described above in relation to the memory card 100. The circuit board 410, electronic device(s) mounted thereto and the conductive wire(s) used to electrically connect the electronic cicuit device(s) to the I/O pads are at least partially encapsulated by an encapsulant body 430 to protect the same from the external environment. Though the body 430 covers a substantial portion of the upper surface 412 of the insulative layer 413, the body 430 does not cover the entirety of the upper surface 412. Rather, the body 430 is formed such that it terminates inwardly from the chamfer 417 in the manner shown in FIG. 4A, thus defining a section 418a of the upper surface 412 which is exposed (i.e., not covered by the body 430). Thus, the body 430 defines a generally planar side surface which extends in spaced, generally parallel relation to the chamfer 417 from the lateral edge 412a to the longitudinal edge 412b. Further, the body 430 is formed such that additional sections 418b, 418c, and 418d of the upper surface 412 are not covered thereby and thus exposed. Each of the sections 418b, 418c, 418d has a generally quadrangular configuration. As such, the body 430, while extending to and in generally flush relation with portions of the lateral edges 412a, 412c and longitudinal edges 412b, 412d, does not extend to the chamfer 417.

The fully formed body 430 defines a generally planar upper surface, as well as generally planar side surfaces which, as indicated above, are substantially flush with portions of respective ones of the lateral edges 412a, 412c and longitudinal edges 412b, 412d of the insulative layer 413. The encapsulant material used to form the body 430 may include, for example, an epoxy, a plastic molding compound, or equivalents thereto, the present invention not being limited to any specific material for the body 430.

Referring now to FIG. 4B, there is shown a raw substrate assembly 450 which will be used to describe one methodology for facilitating the cost effective, simultaneous manufacture of a plurality of modules 405. The substrate assembly 450 includes a substrate 452 which is formed of a suitable printed circuit board material, and in particular that material which will ultimately form the insulative layer 413 of each of the resultant modules 405. It is contemplated that the substrate 452 will be sized so as to be capable of defining at least one circuit board matrix 410a which will ultimately facilitate the creation of six modules 405. In FIG. 4B, one circuit board matrix 410a is shown with particularity. It is contemplated that the substrate 452 will typically be sized to have the capability of allowing three or more circuit board matrices 410a to be defined thereon.

As indicated above, it is contemplated that each circuit board matrix 410a included on the substrate 452 will be configured to ultimately facilitate the formation of six modules 405. Thus, within each circuit board matrix 410a are six separate circuit boards 410 which each have the aforementioned structural attributes, and are ultimately separated from each other as a result of the saw singulation of the substrate 452 in a prescribed manner. In one of the initial stages of the fabrication process for the module 405, the substrate 452 is patterned in a manner facilitating the formation of six separate conductive patterns and six separate sets of I/O pads upon respective ones of the six insulative layers 413 within each circuit board matrix 410a. Either prior or subsequent to the formation of the conductive patterns and I/O pads within each circuit board matrix 410a, a punching, routing or laser operation is completed upon the substrate 452 in a manner facilitating the formation of six separate triangularly configured openings 454 within each circuit board matrix 410a, each opening 454 being located in a respective one of the insulative layers 413. As will be recognized, the relative positioning of the openings 454 and I/O pads within the circuit boards 410 of the circuit board matrix 410a is such that the spacial relationship between at least one of the I/O pads of each of the six sets thereof and a respective one of the openings 454 is the same as that shown and described above in relation to FIG. 2A, considering that each opening 454 ultimately defines a respective chamfer 417 subsequent to the completion of the singulation process.

To facilitate the formation of the six modules 405 from each circuit board matrix 410a, it is contemplated that the substrate 452 will ultimately be cut or severed along each of four Y axes and each of three X axes. When viewed from the perspective shown in FIG. 4B, each of the four Y axes is generally vertical, with each of the three X axes being generally horizontal and extending substantially perpendicularly relative to the Y axes. Due to the orientations of the X and Y axes relative to each other, the layout of each circuit board matrix 410a lends itself to the ultimate fabrication of six modules 405. The layout of such modules 405 prior to the singulation of the substrate assembly 450 is in two horizontal rows of three (defined by the X axes) and three vertical columns of two (defined by the Y axes). It is contemplated that the patterning of the substrate 452 to define the conductive patterns and I/O pads will be facilitated such that the openings 454 are located at common corners of respective ones of the circuit boards 410 within the circuit board matrix 410a. As indicated above, the number of openings 454 included in each circuit board matrix 410a corresponds to the number of modules 405 which will ultimately be defined thereby when the substrate 452 is saw singulated along the X and Y axes.

Subsequent to the formation of the conductive patterns, I/O pads and openings 454 within each circuit board matrix 410a of the substrate 452, the electronic circuit devices are attached to each of the circuit boards 410 within the circuit board matrix 410a, and electrically connected to a corresponding one of the conductive patterns through the use of the conductive wires. Thereafter, a mold cap 430a is formed on the substrate 452 in a manner covering a portion of the circuit board matrix 410a. As is seen in FIG. 4B, the mold cap 430a is formed such that the electronic circuit devices, conductive wires and portions of each of the circuit boards 410 within the corresponding circuit board matrix 410a are covered in the same manner described above in relation to FIG. 4A. In this regard, the mold, which has a structure corresponding to the ultimate shape of the mold cap 430a, makes direct contact with the sections 418a, 418b, 418c, 418d of each circuit board 410 within the circuit board matrix 410a, thus effectively covering and sealing each of the openings 454. As a result, since the mold shields the openings 454, the encapsulant used to form the mold cap 430a does not flow to the lower surface of any one of the circuit boards 410 included in the circuit board matrix 410a during the process of forming the mold cap 430a, thus insuring that no contamination of any lower surface of any circuit board 410 occurs. Due to the contact between the mold and the sections 418a, 418b, 418c, 418d of each circuit board 410 within the circuit board matrix 410a, such sections 418a, 418b, 418c, 418d remain uncovered by the mold cap 430a upon the completion of the formation thereof.

Subsequent to the formation of the mold cap 430a, the substrate 452 is subjected to a saw singulation process along the X and Y axes of each circuit board matrix 410a. Such singulation effectively separates each circuit board matrix 410a into six separate modules 405. As will be recognized, the singulation along the three X axes defines the lateral edges 412a, 412c of the resultant six modules 405, with the singulation along the four Y axes facilitating the formation of the longitudinal edges 412b, 412d of the resultant six modules 405. As indicated above, the formation of the openings 454 within each circuit board matrix 410a ultimately facilitates the formation of each chamfer 417 within a respective one of the six resultant modules 405. The singulation of the mold cap 430a along the X and Y axes facilitates the formation of the bodies 430 of the resultant modules 405. After each module 405 has been fully formed as a result of the completion of the above-described singulation process, a cover may be attached to each such module 405, thus completing the fabrication of the memory card.

Referring now to FIG. 5, there is shown in cross-section a memory card 500 constructed in accordance with another embodiment of the present invention. The memory card 500 represents a slight variation of the memory cards 100, 200 described above in relation to other embodiments of the present invention. The memory card 500 includes a module 505 including a circuit board 510 and body 530 for encapsulating a plurality of electronic circuit devices mounted and electrically connected to the circuit board 510. The module 505 may mirror the structural attributes of any one of the above-described modules 105, 205 and 405. The module 505 of the memory card 500 is covered by a cover 507 which may mirror the structural and functional attributes of the above-described cover 107. In this regard, the cover 507 includes a recess 507a which is sized and configured to accommodate a portion of the module 505 in the same manner described above in relation to the configuration of the recess 107a of the cover 107 relative to the module 105.

The primary distinction between the memory card 500 and those described above in relation to other embodiments of the present invention lies in the inclusion of a lid 508 in the memory card 500. The lid 508 is sized and configured to cover the exposed lower surface of the circuit board 510 and the lower surface of the cover 507. In this regard, it is contemplated that the lid 508 may be provided with one or more openings 508a which is/are sized and configured to facilitate the exposure of the I/O pads 516 of the circuit board 510.

This disclosure provides exemplary embodiments of the present invention. The scope of the present invention is not limited by these exemplary embodiments. Numerous variations, whether explicitly provided for by the specification or implied by the specification, such as variations in structure, dimension, type of material and manufacturing process may be implemented by one of skill in the art in view of this disclosure.

1. A memory card, comprising:
a circuit board having opposed upper and lower circuit board surfaces, multiple side edges, a chamfer extending between a pair of the side edges, a plurality of pads disposed on the lower circuit board surface, and a conductive pattern which is disposed on the upper circuit board surface and electrically connected to the pads;
at least one electronic circuit device attached to the upper circuit board surface and electrically connected to the conductive pattern; and
a body at least partially encapsulating the circuit board and the electronic circuit device such that a section of the upper circuit board surface extending along the entirety of the chamfer and at least one of the side edges is not covered by the body.

2. The memory card of claim 1 wherein:
the circuit board defines first and second opposed lateral side edges and first and second opposed longitudinal side edges;
the chamfer extends between the first lateral side edge and the first longitudinal side edge; and
the body is disposed in spaced relation to the first lateral side edge and the chamfer.

3. The memory card of claim 2 wherein the body extends to an axis on the upper circuit board surface which extends generally perpendicularly between the second longitudinal side edge an approximate point of intersection between the chamfer and the first longitudinal side edge.

4. The memory card of claim 1 wherein the electronic circuit device is electrically connected to the conductive pattern by at least one conductive wire which is covered by the body.

5. The memory card of claim 1 wherein a plurality of the pads are arranged in a row which extends along and in spaced relation to one of the side edges of the circuit board, and at least one of the pads is offset relative to the row and disposed along and in spaced relation to the chamfer.

6. The memory card of claim 1 wherein the electronic circuit device is selected from the group consisting of:
a semiconductor package;
a semiconductor die;
a passive element; and
combinations thereof.

7. The memory card of claim 1 wherein:
the circuit board, the electronic circuit device and the body collectively define a module of the memory card; and
a cover is attached to the body, the cover including a recess which is sized and configured to accommodate the body, the side edges, and the exposed section of the upper circuit board surface.

8. The memory card of claim 7 further in combination with a lid which is attached to the lower circuit board surface and the cover, and includes at least one opening for exposing the pads.

9. The memory card of claim 7 further in combination with a label which is attached to the lower circuit board surface, and includes at least one opening for exposing the pads.

10. A memory card, comprising:
a circuit board having opposed upper and lower circuit board surfaces, multiple side edges, a chamfer extending between a pair of the side edges, a plurality of pads disposed on the lower circuit board surface, and a conductive pattern which is disposed on the upper circuit board surface and electrically connected to the pads;
at least one electronic circuit device attached to the upper circuit board surface and electrically connected to the conductive pattern; and
a body at least partially encapsulating the circuit board and the electronic circuit device such that a section of the upper circuit board surface extending along the entirety of the chamfer is not covered by the body.

11. The memory card of claim 10 wherein:
the circuit board defines first and second opposed lateral side edges and first and second opposed longitudinal side edges;
the chamfer extends between the first lateral side edge and the first longitudinal side edge; and
the body is disposed in spaced relation to the chamfer.

12. The memory card of claim 11 wherein the body extends to an axis on the upper circuit board surface which extends generally between the first lateral side edge and the first longitudinal side edge in spaced relation to the chamfer.

13. The memory card of claim 12 wherein:
the first lateral side edge and the second longitudinal side edge collectively define a first corner of the circuit board;
the second longitudinal side edge and the second lateral side edge collectively define a second corner of the circuit board;
the second lateral side edge and the first longitudinal side edge collectively define a third corner of the circuit board; and
the body is sized and configured such that three corner sections of the upper circuit board surface which include respective ones of the first, second and third corners are not covered by the body.

14. The memory card of claim 13 wherein each of the corner sections has a generally quadrangular configuration.

15. The memory card of claim 10 wherein the electronic circuit device is electrically connected to the conductive pattern by at least one conductive wire which is covered by the body.

16. The memory card of claim 10 wherein a plurality of the pads are arranged in a row which extends along and in spaced relation to one of the side edges of the circuit board, and at least one of the pads is offset relative to the row and disposed along and in spaced relation to the chamfer.

17. The memory card of claim 10 wherein the electronic circuit device is selected from the group consisting of:
a semiconductor package;
a semiconductor die;
a passive element; and
combinations thereof.

18. The memory card of claim 10 wherein:
the circuit board, the electronic circuit device and the body collectively define a module of the memory card; and
a cover is attached to the body, the cover including a recess which is sized and configured to accommodate the body, the side edges, and the exposed section of the upper circuit board surface.

19. The memory card of claim 18 further in combination with a lid which is attached to the lower circuit board surface and the cover, and includes at least one opening for exposing the pads.

20. The memory card of claim 18 further in combination with a label which is attached to the lower circuit board surface, and includes at least one opening for exposing the pads.
